(19) United States
(12) Patent Application Publication
(10) Pub. No.: US 2025/0359462 A1
(43) Pub. Date: Nov. 20, 2025

(54) DISPLAY PANEL AND DISPLAY DEVICE

(71) Applicant: BOE Technology Group Co., Ltd., Beijing (CN)

(72) Inventors: Xiaohu LI, Beijing (CN); Yuxin ZHANG, Beijing (CN); Zhiqiang JIAO, Beijing (CN); Liangliang KANG, Beijing (CN); Guangcai YUAN, Beijing (CN)

(73) Assignee: BOE Technology Group Co., Ltd., Beijing (CN)

(21) Appl. No.: 18/854,555

(22) PCT Filed: Feb. 7, 2024
(86) PCT No.: PCT/CN2024/076739

§ 371 Date: Oct. 7, 2024

(30) Foreign Application Priority Data
Mar. 30, 2023 (CN) 202310334309.3

(51) Int. Cl. H10K 59/80; H10K 59/122; H10K 59/19; H10K 102/00; H10K 102/10

(52) U.S. Cl. CPC H10K 59/80522; H10K 59/122; H10K 59/873; H10K 59/879; H10K 59/19; H10K 2102/10; H10K 2102/351

(57) ABSTRACT

Provided is a display panel, which relates to the field of display technology. The display panel includes: a base substrate, having a display region and a peripheral region around the display region; a pixel circuit layer, disposed on a side of the base substrate and in the display region; a pixel defining layer, disposed on a side of the pixel circuit layer away from the base substrate, wherein the pixel defining layer is provided with a plurality of pixel openings; a plurality of electroluminescent layers, disposed in the plurality of pixel openings; a first electrode layer, disposed on a side of the plurality of electroluminescent layers away from the base substrate; and an auxiliary electrode structure and a light-transmissive electrode patterning structure, wherein the auxiliary electrode structure and the electrode patterning structure are disposed on a side of the first electrode layer away from the base substrate.

### CROSS-REFERENCE TO RELATED APPLICATIONS

The present disclosure is a U.S. national stage of international application No. PCT/CN2024/076739, filed on Feb. 7, 2024, which claims priority to Chinese Patent Application No. 202310334309.3, filed on Mar. 30, 2023, and entitled “DISPLAY PANEL AND DISPLAY DEVICE”, the contents of each are incorporated herein by references in their entireties.

### TECHNICAL FIELD

The present disclosure relates to the field of display technology, and in particular, relates to a display panel and a display device.

### BACKGROUND

A display panel is a device capable of implementing a display function.

A display panel includes a base substrate and a first electrode, a plurality of electroluminescent layers, and a second electrode layer which are sequentially disposed on the base substrate. The second electrode layer cooperates with the first electrode to drive the electroluminescent layers to emit light, so as to implement the display function.

### SUMMARY

Embodiments of the present disclosure provide a display panel and a display device. The technical solutions are as follow.

According to some embodiments of the present disclosure, a display panel is provided. The display panel includes:
a base substrate, having a display region and a peripheral region around the display region;
a pixel circuit layer, disposed on a side of the base substrate and in the display region;
a pixel defining layer, disposed on a side of the pixel circuit layer away from the base substrate, wherein the pixel defining layer is provided with a plurality of pixel openings; a plurality of electroluminescent layers, disposed in the plurality of pixel openings;
a first electrode layer, disposed on a side of the plurality of electroluminescent layers away from the base substrate; and
an auxiliary electrode structure and a light-transmissive electrode patterning structure, wherein the auxiliary electrode structure and the electrode patterning structure are disposed on a side of the first electrode layer away from the base substrate, the auxiliary electrode structure includes an auxiliary electrode layer and an auxiliary electrode pattern, one of the auxiliary electrode layer and the auxiliary electrode pattern is in contact with the first electrode layer, an orthographic projection of the electrode patterning structure on the base substrate is overlapped with an orthographic projection of at least one pixel opening of the plurality of pixel openings on the base substrate, and an orthographic projection of the auxiliary electrode pattern on the base substrate is not overlapped with the orthographic projection of the electrode patterning structure on the base substrate.

In some embodiments, the display panel further includes:
a first light extraction layer disposed on disposed on sides of the auxiliary electrode structure and the light-transmissive electrode patterning structure that are away from the base substrate, wherein a refractive index of the first light extraction layer is less than a refractive index of the auxiliary electrode structure and a refractive index of the light-transmissive electrode patterning structure.

In some embodiments, the auxiliary electrode layer is disposed on the side of the first electrode layer away from the base substrate;
the electrode patterning structure is disposed on a side of the auxiliary electrode layer away from the base substrate;
the auxiliary electrode pattern is disposed in a region where no electrode patterning structure is provided on the auxiliary electrode layer, and the orthographic projection of the auxiliary electrode pattern on the base substrate is at least partially overlapped with an orthographic projection of the pixel defining layer on the base substrate.

In some embodiments, the auxiliary electrode pattern includes a first auxiliary electrode sub-pattern at least partially surrounding the pixel opening, wherein in a direction perpendicular to the base substrate, a thickness of the first auxiliary electrode sub-pattern is greater than a thickness of the electrode patterning structure;
the display panel further includes a first planarization layer, wherein the first planarization layer is disposed on a side of the first light extraction layer away from the base substrate, and a refractive index of the first planarization layer is greater than the refractive index of the first light extraction layer.

In some embodiments, the display region includes a plurality of light-emitting regions, each of the plurality of light-emitting regions includes a plurality of light-emitting sub-regions, and each of the plurality of light-emitting sub-regions is provided with at least one electroluminescent layer;
the auxiliary electrode pattern further includes a second auxiliary electrode sub-pattern disposed between the plurality of light-emitting sub-regions, wherein in the direction perpendicular to the base substrate, a thickness of the second auxiliary electrode sub-pattern is greater than the thickness of the electrode patterning structure.

In some embodiments, in the direction perpendicular to the base substrate, a sum of the thickness of the electrode patterning structure and a thickness of the first light extraction layer is less than a thickness of the auxiliary electrode pattern.

In some embodiments, in a direction perpendicular to the base substrate, a thickness of the auxiliary electrode pattern is less than or equal to a thickness of the electrode patterning structure.

In some embodiments, the electrode patterning structure is disposed on the side of the first electrode layer away from the base substrate;
the auxiliary electrode pattern is disposed in a region where no electrode patterning structure is provided on the auxiliary electrode layer;
the auxiliary electrode layer is disposed on a side of the auxiliary electrode pattern away from the base substrate.

In some embodiments, the pixel defining layer includes a partition structure disposed between at least two electroluminescent layers of the plurality of electroluminescent layers; wherein
an orthographic projection of the partition structure on the base substrate is within the orthographic projection of the auxiliary electrode pattern on the base substrate.

In some embodiments, the first electrode layer, the electrode patterning structure and the auxiliary electrode pattern are formed by an evaporation process.

In some embodiments, the display panel further includes: a lens array, wherein the lens array is disposed on a side of the electrode patterning structure away from the base substrate, and the lens array includes at least one lens structure disposed in the display region;
the display panel further includes a second planarization layer, wherein the second planarization layer is disposed between the lens array and the first light extraction layer, and a refractive index of a material of the second planarization layer is less than a refractive index of a material of the lens structure.

In some embodiments, the display region includes a plurality of light-emitting regions, each of the plurality of light-emitting regions includes a plurality of light-emitting sub-regions, and each of the plurality of light-emitting sub-regions is provided with at least one electroluminescent layer;
the lens array includes a plurality of lens structures respectively disposed in the plurality of light-emitting sub-regions.

In some embodiments, the auxiliary electrode layer is disposed on the side of the first electrode layer away from the base substrate, the electrode patterning structure is disposed on a side of the auxiliary electrode layer away from the base substrate, and the auxiliary electrode pattern is disposed in a region where no electrode patterning structure is provided on the auxiliary electrode layer;
the lens structure is disposed on the side of the electrode patterning structure away from the base substrate.

In some embodiments, the display region includes a plurality of light-emitting regions, each of the plurality of light-emitting regions includes a plurality of light-emitting sub-regions, and each of the plurality of light-emitting sub-regions is provided with at least one electroluminescent layer;
the auxiliary electrode pattern includes a first auxiliary electrode sub-pattern surrounding the light-emitting region and a second auxiliary electrode sub-pattern disposed between the plurality of light-emitting sub-regions, wherein in a direction perpendicular to the base substrate, a thickness of the auxiliary electrode pattern is greater than a thickness of the electrode patterning structure.

In some embodiments, the display panel further includes: a spacer layer, wherein the spacer layer is disposed on the side of the electrode patterning structure away from the base substrate, and the lens structure is disposed on a side of the spacer layer away from the base substrate.

In some embodiments, the display panel further includes: an encapsulation layer; wherein the encapsulation layer includes the first light extraction layer and a first light-transmissive layer, a second light-transmissive layer, and a third light transmittance layer sequentially stacked on the first light extraction layer, wherein a refractive index of the first light-transmissive layer is greater than a refractive index of the second light-transmissive layer and the refractive index of the first light extraction layer, and the refractive index of the second light-transmissive layer is less than a refractive index of the third light-transmissive layer.

In some embodiments, a material of the first light extraction layer includes silicon oxide, a material of the first light-transmissive layer includes silicon nitride oxide or silicon nitride, a material of the second light-transmissive layer includes a resin material, and a material of the third light-transmissive layer includes silicon nitride.

In some embodiments, a thickness of the first light extraction layer ranges from 10 nm to 1000 nm, thicknesses of the first light-transmissive layer and the third light-transmissive layer range from 600 nm to 1200 nm, and a thickness of the second light-transmissive layer ranges from 3 μm to 5 μm.

In some embodiments, the display panel further includes: an encapsulation layer; wherein the encapsulation layer is disposed on a side of the first light extraction layer away from the base substrate, and the encapsulation layer includes a first light-transmissive layer, a second light-transmissive layer, and a third light transmittance layer sequentially which are stacked in a direction away from the base substrate, wherein a refractive index of the first light-transmissive layer is greater than a refractive index of the second light-transmissive layer and the refractive index of the first light extraction layer, and the refractive index of the second light-transmissive layer is less than a refractive index of the third light-transmissive layer.

In some embodiments, a material of the auxiliary electrode layer includes a transparent conductive oxide, and a material of the auxiliary electrode pattern includes a conductive metal material.

In some embodiments, a thickness of the auxiliary electrode layer ranges from 50 nm to 1000 nm, and a thickness of the electrode patterning structure ranges from 5 nm to 100 nm.

According to some embodiments of the present disclosure, a display panel is provided. The display panel includes:
a base substrate, having a display region and a peripheral region around the display region, wherein the display region includes a plurality of light-emitting regions, and each of the plurality of light-emitting regions includes a plurality of light-emitting sub-regions;
a plurality of electroluminescent layers, disposed on the base substrate;
a first electrode layer, disposed on a side of the plurality of electroluminescent layers away from the base substrate; and
an auxiliary electrode structure and a light-transmissive electrode patterning structure, wherein the auxiliary electrode structure and the electrode patterning structure are disposed on a side of the first electrode layer away from the base substrate, the auxiliary electrode structure includes an auxiliary electrode layer and an auxiliary electrode pattern, one of the auxiliary electrode layer and the auxiliary electrode pattern is in contact with the first electrode layer, the auxiliary electrode pattern is provided with a plurality of auxiliary electrode openings, an orthographic projection of at least one auxiliary electrode opening of the plurality of auxiliary electrode openings on the base substrate is at least partially within the light-emitting sub-region, and the electrode patterning structure includes a plurality of electrode patterning sub-structures, the electrode patterning sub-structures being disposed in the auxiliary electrode openings.

According to some embodiments of the present disclosure, a display device is provided. The display device includes a display panel. The display panel includes:
a base substrate, having a display region and a peripheral region around the display region;
a pixel circuit layer, disposed on a side of the base substrate and in the display region;
a pixel defining layer, disposed on a side of the pixel circuit layer away from the base substrate, wherein the pixel defining layer is provided with a plurality of pixel openings;
a plurality of electroluminescent layers, disposed in the plurality of pixel openings;
a first electrode layer, disposed on a side of the plurality of electroluminescent layers away from the base substrate; and
an auxiliary electrode structure and a light-transmissive electrode patterning structure, wherein the auxiliary electrode structure and the electrode patterning structure are disposed on a side of the first electrode layer away from the base substrate, the auxiliary electrode structure includes an auxiliary electrode layer and an auxiliary electrode pattern, one of the auxiliary electrode layer and the auxiliary electrode pattern is in contact with the first electrode layer, an orthographic projection of the electrode patterning structure on the base substrate is overlapped with an orthographic projection of at least one pixel opening of the plurality of pixel openings on the base substrate, and an orthographic projection of the auxiliary electrode pattern on the base substrate is not overlapped with the orthographic projection of the electrode patterning structure on the base substrate.

According to some embodiments of the present disclosure, a method for manufacturing a display panel is provided. The method includes:
forming a pixel circuit layer on a base substrate, wherein the base substrate has a display region and a peripheral region around the display region, and the pixel circuit layer is disposed in the display region;
forming a pixel defining layer on a side of the pixel circuit layer away from the base substrate, wherein the pixel defining layer is provided with a plurality of pixel openings;
forming a plurality of electroluminescent layers in the plurality of pixel openings;
forming a first electrode layer on a side of the plurality of electroluminescent layers away from the base substrate; and
forming an auxiliary electrode structure and a light-transmissive electrode patterning structure on a side of the first electrode layer away from the base substrate, wherein the auxiliary electrode structure includes an auxiliary electrode layer and an auxiliary electrode pattern, one of the auxiliary electrode layer and the auxiliary electrode pattern is in contact with the first electrode layer, an orthographic projection of the electrode patterning structure on the base substrate is overlapped with an orthographic projection of at least one pixel opening of the plurality of pixel openings on the base substrate, and an orthographic projection of the auxiliary electrode pattern on the base substrate is not overlapped with the orthographic projection of the electrode patterning structure on the base substrate.

In some embodiments, the method further includes:
forming a first light extraction layer on sides of the auxiliary electrode structure and the electrode patterning structure that are away from the base substrate, wherein a refractive index of the first light extraction layer is less than a refractive index of the auxiliary electrode structure and a refractive index of the electrode patterning structure.

In some embodiments, forming the auxiliary electrode structure and the light-transmissive electrode patterning structure on the side of the first electrode layer away from the base substrate includes:
forming the auxiliary electrode layer on the side of the first electrode layer away from the base substrate;
forming the electrode patterning structure on the side of auxiliary electrode layer away from the base substrate; and
forming the auxiliary electrode pattern in a region where no electrode patterning structure is formed on the auxiliary electrode layer, wherein the orthographic projection of the auxiliary electrode pattern on the base substrate is at least partially overlapped with an orthographic projection of the pixel defining layer on the base substrate.

In some embodiments, forming the first electrode layer on the side of the plurality of electroluminescent layers away from the base substrate includes:
forming the first electrode layer on the side of the plurality of electroluminescent layers away from the base substrate by an evaporation process;
forming the auxiliary electrode structure and the light-transmissive electrode patterning structure on the side of the first electrode layer away from the base substrate includes:
forming the electrode patterning structure on the side of the first electrode layer away from the base substrate by an evaporation process;
forming the auxiliary electrode pattern in a region where no electrode patterning structure is formed on the first electrode layer by an evaporation process; and
forming the auxiliary electrode layer on the side of the auxiliary electrode pattern away from the base substrate by an evaporation process.

### BRIEF DESCRIPTION OF DRAWINGS

For clearer descriptions of the technical solutions in the embodiments of the present disclosure, the following briefly introduces the accompanying drawings required for describing the embodiments. The accompanying drawings in the following descriptions show merely some embodiments of the present disclosure, and persons of ordinary skill in the art may still derive other drawings from these accompanying drawings without creative effort.

FIG. 1 is a schematic structural diagram of a current display panel;

FIG. 2 is a schematic structural diagram of another current display panel;

FIG. 3 is a schematic structural diagram of a region of another display panel in which a partition structure is disposed;

FIG. 4 is a schematic structural diagram of a display panel according to some embodiments of the present disclosure;

FIG. 5 is a schematic diagram of a sectional structure of the display panel shown in FIG. 4;

FIG. 6 is a schematic structural diagram of another display panel according to some embodiments of the present disclosure;

FIG. 7 is atop view of the display panel shown in FIG. 6;

FIG. 8 is a schematic structural diagram of still another display panel according to some embodiments of the present disclosure;

FIG. 9 is a schematic structural diagram of still another display panel according to some embodiments of the present disclosure;

FIG. 10 is a schematic structural diagram of still another display panel according to some embodiments of the present disclosure;

FIG. 11 is a schematic structural diagram of still another display panel according to some embodiments of the present disclosure;

FIG. 12 is a top view of the display panel shown in FIG. 11;

FIG. 13 is a schematic structural diagram of still another display panel according to some embodiments of the present disclosure;

FIG. 14 is a top view of the display panel shown in FIG. 13;

FIG. 15 is a schematic structural diagram of still another display panel according to some embodiments of the present disclosure;

FIG. 16 is a schematic structural diagram of still another display panel according to some embodiments of the present disclosure;

FIG. 17 is a schematic structural diagram of still another display panel according to some embodiments of the present disclosure;

FIG. 18 is a schematic structural diagram of still another display panel according to some embodiments of the present disclosure;

FIG. 19 is a schematic structural diagram of still another display panel according to some embodiments of the present disclosure;

FIG. 20 is a schematic structural diagram of still another display panel according to some embodiments of the present disclosure;

FIG. 21 is a schematic diagram of a top view structure of the display panel shown in FIG. 20;

FIG. 22 is a sectional schematic diagram of the display panel shown in FIG. 4;

FIG. 23 is a flowchart of a method for manufacturing a display panel according to some embodiments of the present disclosure;

FIG. 24 is a flowchart of forming an auxiliary electrode structure and a light-transmissive electrode patterning structure in the embodiment shown in FIG. 23;

FIG. 25 is another flowchart of forming an auxiliary electrode structure and a light-transmissive electrode patterning structure in the embodiment shown in FIG. 23.

Specific embodiments of the present disclosure have been shown in the above accompanying drawings, and will be described in detail later. These accompanying drawings and textual descriptions are not intended to limit the scope of the ideas of the present disclosure in any way, but rather to illustrate the concepts of the present disclosure for those skilled in the art by reference to particular embodiments.

### DETAILED DESCRIPTION

To make the objects, technical solutions and advantages of the present disclosure clearer, the embodiments of the present disclosure are further described in detail hereinafter with reference to the accompanying drawings.

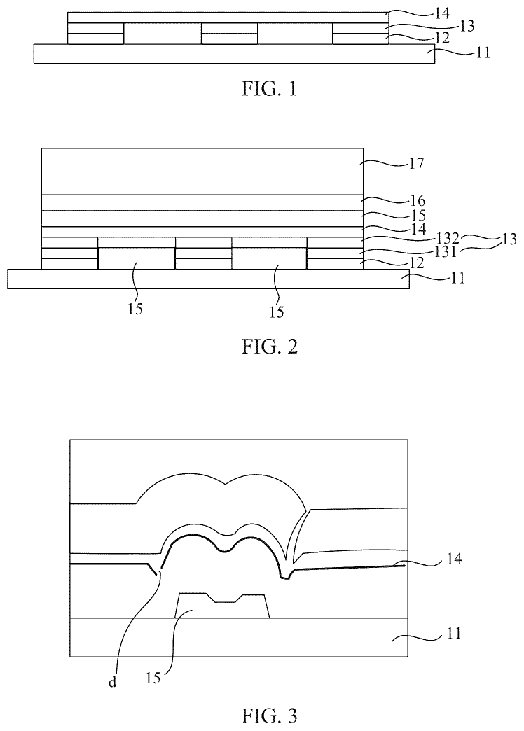

A display panel is a device capable of implementing a display function. FIG. 1 is a schematic structural diagram of a current display panel. The display panel includes a base substrate 11, an anode 12, a plurality of electroluminescent layers 13, and a cathode layer 14. The anode 12, the electroluminescent layer 13, and the cathode layer 14 are sequentially stacked on the base substrate, and the plurality of electroluminescent layers 13 are driven by structures sharing a cathode, that is, each of the electroluminescent layers 13 has an independent anode 12, and the plurality of electroluminescent layers 13 share a cathode layer 14, which is an entire layer structure. In this way, the electroluminescent layers 13 can be separately driven by the plurality of anodes 12 and the cathode layer 14.

However, the cathode layer 14 in the above display panel has a large overall structure, and the cathode layer 14 may be fractured due to the unevenness of the structures under the cathode layer 14 and the bending of the display panel under force. As a result, the electroluminescent layers at the fracture points may not operate normally, resulting in a lower yield, lower durability, and shorter life of the display panel.

The above problem is particularly serious in another display panel. Exemplarily, referring to FIG. 2, which is a schematic structural diagram of another current display panel, the display panel includes a base substrate 11, an anode 12, a plurality of electroluminescent layers 13, and a cathode layer 14. The anode 12, the electroluminescent layers 13, and the cathode layer 14 are sequentially stacked on the base substrate, and different from the electroluminescent layer in the display panel shown in FIG. 1, the electroluminescent layer 13 includes two stacked sub-electroluminescent layers 131 (such a structure is a tandem organic light-emitting diode (Tandem OLED)). Similarly, the upper and lower stacked electroluminescent layers 13 are driven by structures sharing a cathode, the two stacked sub-electroluminescent layers 131 share an anode 12 below, and the plurality of electroluminescent layers 13 share a cathode layer 14, which is an entire layer structure. In this way, the tandem structure of the two stacked sub-electroluminescent layers 131 is achieved, and the electroluminescent layers 13 are respectively driven by the plurality of anodes 12 and cathode layer 14.

In addition, in the direction parallel to the base substrate 11, a partition structure 15 is further provided between the electroluminescent layers 13, and the partition structure 15 is configured to partition some high mobility film layers (e.g., a charge generation layer) in the display panel so as to improve the display effect. However, the partition structure 15 may break through the cathode layer 14 above, causing short-circuits in some regions of the cathode layer 14. Exemplarily, as shown in FIG. 3, which is a schematic structural diagram of a region of another display panel in which a partition structure is disposed, the cathode layer 14 above has a fracture d under the action of the partition structure 15.

In addition, the display panel further includes a first light extraction layer 15 and a second light extraction layer 16 which are formed on the cathode layer 14. The refractive index of the first light extraction layer 15 is greater than the refractive index of the second light extraction layer 16, thereby achieving the effect of light extraction. An encapsulation layer 17 is further provided on the second light extraction layer 16.

The embodiments of the present disclosure provide a display panel, a display device, and a method for manufacturing a display panel, which are capable of solving some problems in the related art.

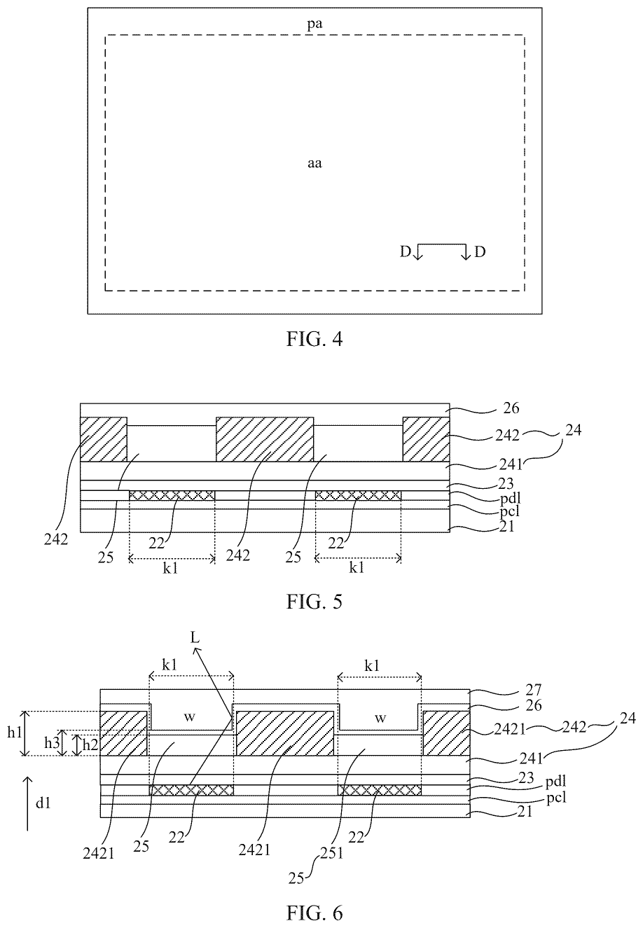

FIG. 4 is a schematic structural diagram of a display panel according to some embodiments of the present disclosure, and FIG. 5 is a schematic diagram of a sectional structure of the display panel shown in FIG. 4 (FIG. 5 may be a sectional view of FIG. 4 at position DD). Referring to FIG. 4 and FIG. 5, the display panel includes:
a base substrate 21, and the base substrate 21 has a display region aa and a peripheral region pa around the display region aa;
a pixel circuit layer pcl, disposed on a side of the base substrate 21 and disposed in the display region aa;
a pixel defining layer pdl, disposed on the side of the pixel circuit layer pcl away from the base substrate 21 and provided with a plurality of pixel openings k1;
a plurality of electroluminescent layers 22, disposed in the plurality of pixel openings k1;
a first electrode layer 23, disposed on the side of the plurality of electroluminescent layers 22 away from the base substrate 21;
an auxiliary electrode structure 24 and a light-transmissive electrode patterning structure 25. The auxiliary electrode structure 24 and the electrode patterning structure 25 are disposed on the side of the first electrode layer 23 away from the base substrate 21. The auxiliary electrode structure 24 includes an auxiliary electrode layer 241 and an auxiliary electrode pattern 242, and one of the auxiliary electrode layer 241 and the auxiliary electrode pattern 242 is in contact with the first electrode layer 23. The orthographic projection of the electrode patterning structure 25 on the base substrate 21 is overlapped with the orthographic projection of at least one pixel opening k1 of the plurality of pixel openings k1 on the base substrate 21, and the orthographic projection of the auxiliary electrode pattern 242 on the base substrate 21 is not overlapped with the orthographic projection of the electrode patterning structure 25 on the base substrate 21.

In summary, the embodiments of the present disclosure provide a display panel. In the display panel, an auxiliary electrode structure including an auxiliary electrode layer and an auxiliary electrode pattern is provided on the first electrode layer, and the auxiliary electrode layer or the auxiliary electrode pattern is in contact with the first electrode layer. With this structure, on the one hand, the first electrode layer can be protected, and the probability of fracture of the first electrode layer can be reduced; and on the other hand, in the event that the first electrode layer fractures, the first electrode layer can be electrically connected to the auxiliary electrode structure at the position of fracture, which can prevent the electrical function of the first electrode layer from damage, thereby solving the problem of the lower yield of the display panel in the related art and improving the yield of the display panel.

The pixel circuit layer pcl involved in the embodiments of the present disclosure is configured to drive the electroluminescent layers, and the pixel circuit layer includes some circuit structures such as thin film transistors.

In an exemplary embodiment, referring to FIG. 5, the display panel provided in the embodiments of the present disclosure further includes a first light extraction layer 26, and the first light extraction layer 26 is disposed on the sides, away from the base substrate 21, of the auxiliary electrode structure 24 and the light-transmissive electrode patterning structure 25. The refractive index of the first light extraction layer 26 is less than the refractive index of the auxiliary electrode structure 24 and the refractive index of the light-transmissive electrode patterning structure 25. In this way, the first light extraction layer, the auxiliary electrode structure, and the light-transmissive electrode patterning structure can cooperate to implement the light extraction function, which improves the light output efficiency of the front side of the display panel. The auxiliary electrode structure and the light-transmissive electrode patterning structure are reused as a part of a light extraction structure, which reduces the influence of the auxiliary electrode structure and the light-transmissive electrode patterning structure on the display panel.

It should be noted that users usually view the display panel in front of the display panel, and if there is a lot of large-angle output light in the light emitted from the display panel, there will be a waste of light. In the display panel provided in the embodiments of the present disclosure, the refractive index of the first light extraction layer 26 is less than the refractive index of the auxiliary electrode structure 24 and the refractive index of the light-transmissive electrode patterning structure 25, and when light emitted from the electroluminescent layer 22 below passes through the auxiliary electrode structure 24 and the light-transmissive electrode patterning structure 25 and irradiates an interface of the first light extraction layer 26, the light is directed from an optically denser medium to an optically thinner medium. When an incident angle of the light is greater than or equal to a critical angle of total reflection, the light is totally reflected and cannot be incident into the first light extraction layer 26. The light continues to be reflected in the auxiliary electrode structure 24 and the light-transmissive electrode patterning structure 25, and the light is incident into the first light extraction layer 26 until the incident angle of the light when the light irradiates the interface of the first light extraction layer 26 is less than the critical angle. In this way, large-angle light can be prevented from being emitted out of the display panel, and the light output efficiency of the front side of the display panel is improved. When users view the display panel in front of the display panel, the display panel is brighter, which improves the user experience.

In the embodiments of the present disclosure, the light output efficiency of the front side refers to the ratio of light with an output angle less than a specified angle to the light emitted from the display panel (the specified angle is preset, e.g., 30 degrees to 60, etc., which is not limited in the embodiments of the present disclosure).

It should be noted that, in the embodiments of the present disclosure, the electrode patterning structure 25 is a structure which is used in cooperation to form the auxiliary electrode pattern 242, and the electrode patterning structure 25 is made of a material that selectively precipitates the material of the auxiliary electrode pattern 242, that is, it is difficult for the material of the auxiliary electrode pattern 242 to be deposited on the electrode patterning structure 25, and when the auxiliary electrode pattern 242 is formed after the electrode patterning structure 25 is provided, the auxiliary electrode pattern 242 is formed only in a region where no electrode patterning structure 25 is provided. In the embodiments of the present disclosure, the auxiliary electrode layer and the auxiliary electrode pattern are stacked.

In an exemplary embodiment, the auxiliary electrode layer 241 is a light-transmissive film layer. For example, the material of the auxiliary electrode layer 241 includes a transparent conductive oxide. Since the auxiliary electrode layer 241 is an entire layer structure, the auxiliary electrode layer 241 is made of a transparent conductive oxide with a high light transmittance, e.g., indium zinc oxide (IZO) and so forth, and the transparent conductive oxide has a certain resistance to water and oxygen. Thus, the auxiliary electrode layer 241 can increase the durability of the display panel. In order to reduce the possibility of fracture of the first electrode layer, the auxiliary electrode layer 241 is thicker. For example, the thickness of the auxiliary electrode layer ranges from 50 nm to 1000 nm.

The material of the auxiliary electrode pattern 242 includes a conductive metal material. Since the auxiliary electrode pattern 242 has less impact on the display region, the auxiliary electrode pattern 242 is made of a conductive metal material with strong conductivity, such as argentum and magnesium.

In an exemplary embodiment, the first electrode layer 23 is a cathode layer, and correspondingly, the auxiliary electrode layer 241 is an auxiliary cathode layer, the auxiliary electrode pattern 242 is an auxiliary cathode pattern, and the electrode patterning structure 25 is a cathode patterning structure, and the material of the electrode patterning structure 25 includes a cathode patterning material (CPM). The cathode patterning material includes at least one of
(1) 2-(4-tert-Butylphenyl)-5-(4-biphenylyl)-1,3,4-oxadiazole;
(2) 2-(4-Biphenylyl)-5-phenyl-1,3,4-oxadiazole;
(3) 1,3-Bis(N-carbazolyl)benzene;
(4) 3-(4-biphenylyl)-4-phenyl-5-tert-butylphenyl-1,2,4-triazole;
(5) N,N′-Diphenyl-N,N′-di(2-naphthyl)-(1,1′-biphenyl)-4,4′-diamine;
(6) 4-(1-Naphthalenyl)-3,5-diphenyl-4H-1,2,4-triazole;
(7) 3,5-Bis[4-(1,1-dimethylethyl)phenyl]-4-phenyl-4H-1,2,4-triazole;
(8) 2,5-Bis(1-naphthyl)-1,3,4-oxadiazole;
(9) 2-tert-Butyl-9,10-di(naphth-2-yl)anthracene;
(10) 4,4′-Bis(N-carbazolyl)-1,1′-biphenyl;
(11) Bis(2-methyl-8-quinolinolate)-4-(phenylphenol)aluminum;
(12) 9-[1,1′-Biphenyl]-3-yl-9H-carbazole; and
(13) Tris[2-phenylpyridinato-C²,N]iridium(III).

The thickness of the electrode patterning structure ranges from 5 nm to 100 nm or from 15 nm to 100 nm, which can improve the electrode patterning structure's property of preventing magnesium and argentum from forming films on the surface of the electrode patterning structure.

FIG. 6 is a schematic structural diagram of another display panel according to some embodiments of the present disclosure. The auxiliary electrode layer 241 is disposed on the side of the first electrode layer 23 away from the base substrate 21.

The electrode patterning structure 25 is disposed on the side of the auxiliary electrode layer 241 away from the base substrate 21.

The auxiliary electrode pattern 242 is disposed in a region of the auxiliary electrode layer 241 where no electrode patterning structure 25 is provided, and the orthographic projection of the auxiliary electrode pattern 242 on the base substrate 21 is at least partially overlapped with the orthographic projection of the pixel defining layer pdl on the base substrate 21. In this way, it can be ensured that the auxiliary electrode pattern 242 is disposed above the pixel defining layer pdl, such that the auxiliary electrode pattern 242 is electrically connected to the first electrode layer 23 at the fracture when the pixel defining layer pdl breaks through the first electrode layer 23, thereby avoiding display abnormalities.

The auxiliary electrode pattern 242 includes a first auxiliary electrode sub-pattern 2421 at least partially surrounding the pixel opening k1, and in the direction d1 perpendicular to the base substrate 21, the thickness h1 of the first auxiliary electrode sub-pattern 2421 is greater than the thickness h2 of the electrode patterning structure 25. In this way, an undulating structure may be formed on the upper surfaces of the electrode patterning structure 25 and the first auxiliary electrode sub-pattern 2421, and a pit w may be formed at the position of the electrode patterning structure 25. The first light extraction layer 26 is formed on the undulating structure, and the first light extraction layer 26 covers the bottom and sidewalls of the pit w.

In some embodiments, in the direction d1 perpendicular to the base substrate 21, the sum h3 of the thickness h2 of the electrode patterning structure 25 and the thickness h3 of the first light extraction layer 26 is less than the thickness h1 of the auxiliary electrode pattern 242, which can further increase the depth of the pit w and improve the light output efficiency of the front side.

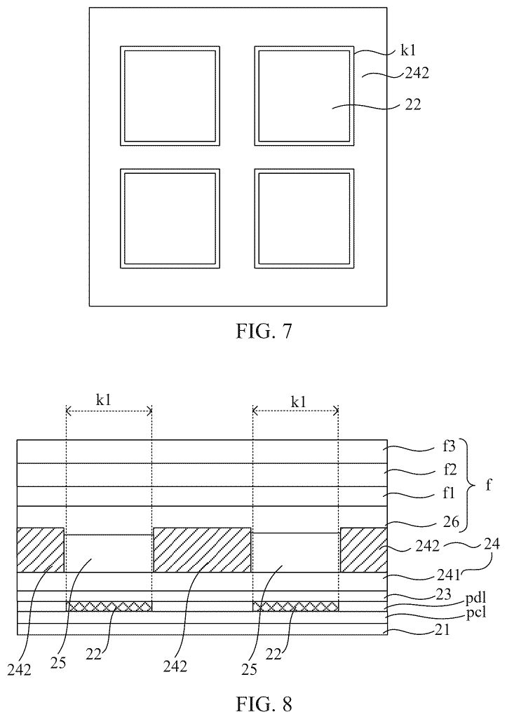

FIG. 7 is a top view of the display panel shown in FIG. 6. Referring to FIG. 6 and FIG. 7, the first auxiliary electrode sub-pattern 2421 is provided with a plurality of openings, each of the openings is provided with a pixel opening k1, and the electroluminescent layer 22 is disposed in the pixel opening k1. It should be noted that in order to clearly illustrate the electroluminescent layer 22, the electrode patterning structure 25 is not shown in FIG. 6, which is not limited.

Referring to FIG. 6, the display panel further includes a first planarization layer 27, and the first planarization layer 27 is disposed on the side of the first light extraction layer 26 away from the base substrate. The refractive index of the first planarization layer 27 is greater than the refractive index of the first light extraction layer 26. The first planarization layer 27 fills the pit w. Since the refractive index of the first planarization layer 27 is greater than the refractive index of the first light extraction layer 26, when light L emitted from the electroluminescent layer 22 is directed from the first planarization layer 27 in the pit w to the first light extraction layer 26 on the sidewalls of the pit w, light L is directed from an optically denser medium to an optically thinner medium, and part of the light L with an incident angle greater than the critical angle is totally reflected and is directed to the front side of the display panel, thereby increasing the light output efficiency of the front side of the display panel. That is, in the display panel provided in the embodiments of the present disclosure, the thickness of the first auxiliary electrode sub-pattern 2421 is greater than the thickness of the electrode patterning structure 25, thereby increasing the light output efficiency of the front side of the display panel. In addition, the refractive index of the electrode patterning structure 25 is equal or approximate to the refractive index of the auxiliary electrode layer 241, thereby reducing the influence on the light at the interface of the electrode patterning structure 25 and the auxiliary electrode layer 241.

The first planarization layer 27 is prepared by an ink jet printing (IJP) process. The material of the first planarization layer 27 includes polyurethane, and the thickness of the first planarization layer 27 ranges from 3 μm to 5 μm.

FIG. 8 is a schematic structural diagram of still another display panel according to some embodiments of the present disclosure. The display panel further includes an encapsulation layer f, and the encapsulation layer f includes the first light extraction layer 26 and a first light-transmissive layer f1, a second light-transmissive layer f2, and a third light-transmissive layer f3 sequentially stacked on the first light extraction layer 26. The refractive index of the first light-transmissive layer f1 is greater than the refractive index of the second light-transmissive layer f2 and the refractive index of the first light extraction layer 26, and the refractive index of the second light-transmissive layer f2 is less than the refractive index of the third light-transmissive layer f3. Therefore, a structure in which materials with a high refractive index and materials with a low refractive index are arranged alternately is acquired, which can improve the light output efficiency of the front side of the display panel.

In this structure, the first light extraction layer 26 is a layer in the encapsulation layer f, and the first light extraction layer 26 is prepared by a chemical vapor deposition (CVD) process or a single atomic layer deposition (ALD) process.

The encapsulation layer f is a thin film encapsulation (TFE) layer.

In some embodiments, the material of the first light extraction layer 26 includes silicon oxide (SiO), the material of the first light-transmissive layer f1 includes silicon oxynitride (SiON) or silicon nitride (SiN), the material of the second light-transmissive layer includes a resin material, and the material of the third light-transmissive layer f3 includes silicon nitride (SiN). The second light-transmissive layer is prepared by an IJP process.

In some embodiments, the thickness of the first light extraction layer 26 ranges from 10 nm to 1000 nm (e.g., the thickness of the first light extraction layer 26 ranges from 10 nm to 100 nm), the thicknesses of the first light-transmissive layer f1 and the third light-transmissive layer f3 range from 600 nm to 1200 nm, and the thickness of the second light-transmissive layer f2 ranges from 3 μm to 5 μm.

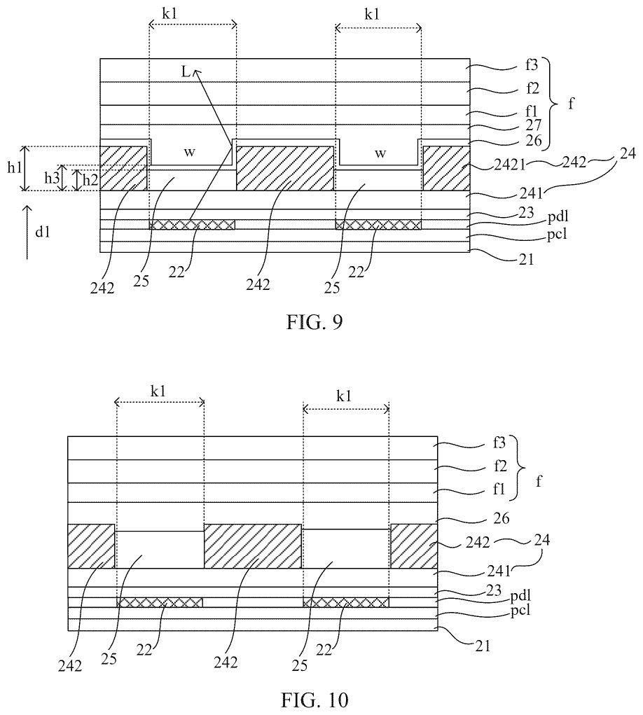

Certainly, the display panel shown in FIG. 6 may also include an encapsulation layer f. Exemplarily, as shown in FIG. 9, which is a schematic structural diagram of still another display panel according to some embodiments of the present disclosure, the display panel further includes an encapsulation layer f. The encapsulation layer f includes the first light extraction layer 26, the first planarization layer 27, and a first light-transmissive layer f1, a second light-transmissive layer f2, and a third light-transmissive layer f3 sequentially stacked on the first planarization layer 27. The refractive index of the first light-transmissive layer f1 is greater than the refractive index of the second light-transmissive layer f2, and the refractive index of the second light-transmissive layer f2 is less than the refractive index of the third light-transmissive layer f3. Therefore, a structure in which materials with a high refractive index and materials with a low refractive index are arranged alternately is acquired, which can improve the light output efficiency of the front side of the display panel. The encapsulation layer f is a thin film encapsulation (TFE) layer. The refractive index of the first light-transmissive layer f1 is equal or approximate to the refractive index of the first planarization layer 27, thereby reducing the influence on the light at the interface of the first light-transmissive layer f1 and the first planarization layer 27.

In this structure, the first light extraction layer 26 and the first planarization layer 27 are film layers in the encapsulation layer f.

Certainly, the first light extraction layer 26 may not belong to the encapsulation layer f. Exemplarily, as shown in FIG. 10, which is a schematic structural diagram of still another display panel according to some embodiments of the present disclosure, the display panel further includes an encapsulation layer f. The encapsulation layer f is disposed on the side of the first light extraction layer 26 away from the base substrate 21, and the encapsulation layer f includes a first light-transmissive layer f1, a second light-transmissive layer f2, and a third light-transmissive layer f3 sequentially stacked in the direction away from the base substrate 21. The refractive index of the first light-transmissive layer f1 is greater than the refractive index of the second light-transmissive layer f2 and the refractive index of the first light extraction layer 26, and the refractive index of the second light-transmissive layer f2 is less than the refractive index of the third light-transmissive layer f3. The encapsulation layer f is a thin film encapsulation layer. In this structure, the first light extraction layer 26 is a film layer independently disposed between the encapsulation layer f and the auxiliary electrode structure 24. The first light extraction layer 26 is prepared by a CVD process or a single ALD process.

In some embodiments, the material of the first light extraction layer 26 includes silicon oxide (SiO), the material of the first light-transmissive layer f1 includes silicon oxynitride (SiON) or silicon nitride (SiN), the material of the second light-transmissive layer includes a resin material, and the material of the third light-transmissive layer f3 includes silicon nitride (SiN). The second light-transmissive layer is prepared by an IJP process.

In some embodiments, the thickness of the first light extraction layer 26 ranges from 10 nm to 1000 nm (e.g., the thickness of the first light extraction layer 26 ranges from 10 nm to 100 nm), the thicknesses of the first light-transmissive layer f1 and the third light-transmissive layer f3 range from 600 nm to 1200 nm, and the thickness of the second light-transmissive layer f2 ranges from 3 μm to 5 μm.

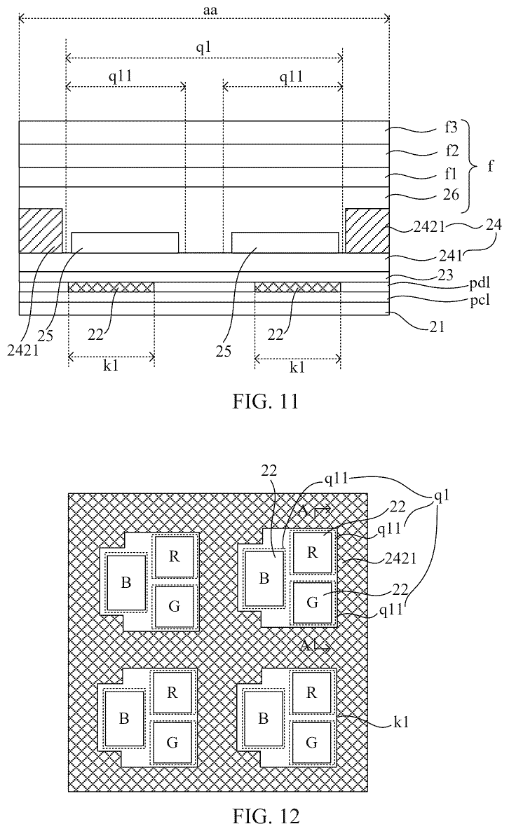

In the above embodiments, one electroluminescent layer is provided in each display region. However, in the display panel provided in the present disclosure, more electroluminescent layers may be provided in each display region. Exemplarily, FIG. 11 is a schematic structural diagram of still another display panel according to some embodiments of the present disclosure, and FIG. 12 is a top view of the display panel shown in FIG. 11 (FIG. 11 may be a schematic diagram of a sectional structure at A-A in FIG. 12). Referring to FIG. 11 and FIG. 12, the display region aa includes a plurality of light-emitting regions q1, each of the light-emitting regions q1 includes a plurality of light-emitting sub-regions q11, and each of the light-emitting sub-regions q11 is provided with at least one electroluminescent layer 22. FIG. 11 illustrates a structure in which each light-emitting region q1 includes three light-emitting sub-regions q11, and each light-emitting sub-region q1 is provided with one electroluminescent layer 22. The three light-emitting sub-regions q11 are a red light-emitting sub-region, a green light-emitting sub-region, and a blue light-emitting sub-region, and accordingly, the three light-emitting sub-regions q11 are respectively provided with a blue electroluminescent layer B, a red electroluminescent layer R, and a green electroluminescent layer G. It should be noted that in the display panel shown in the embodiments of the present disclosure, the light-emitting region is a pixel region, and the light-emitting sub-region is a sub-pixel region, and the structure in each sub-pixel region form a sub-pixel, and the structures in each light-emitting region form a pixel.

In addition, in this structure, the shape of the opening in the first auxiliary electrode sub-pattern 2421 surrounding the light-emitting region q1 is determined by the arrangement shape of the electroluminescent layers in the light-emitting regions. Exemplarily, as shown in FIG. 12, when the three electroluminescent layers 22 are arranged in a T-shape, the shape of the opening in the first auxiliary electrode sub-pattern 2421 is in a T-shape, which is not limited in the embodiments of the present disclosure.

In the display panel shown in FIG. 11 and in FIG. 12, no auxiliary electrode pattern is provided between the light-emitting sub-regions q11, which can increase the aperture rate of the display panel.

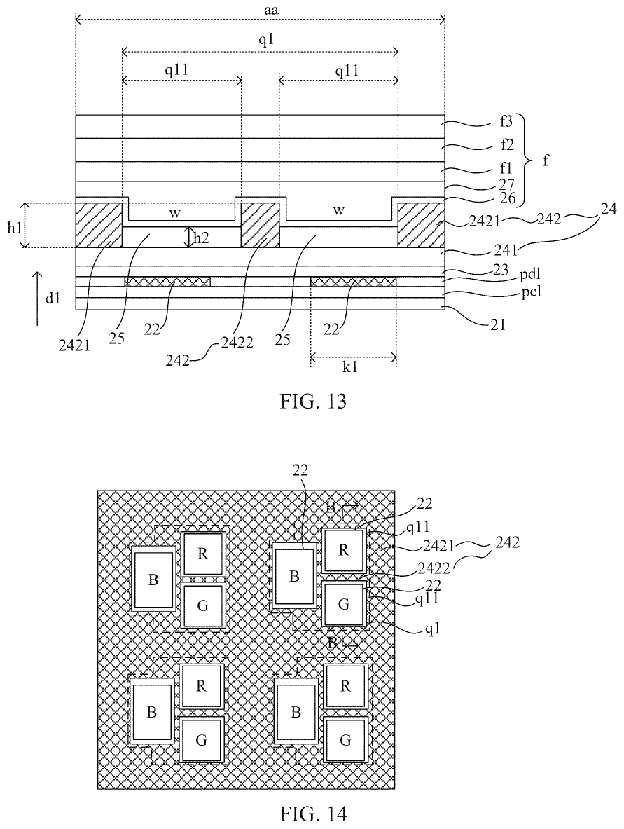

FIG. 13 is a schematic structural diagram of still another display panel according to some embodiments of the present disclosure, and FIG. 14 is a top view of the display panel shown in FIG. 13 (FIG. 13 may be a schematic diagram of a sectional structure at A-A in FIG. 14). Referring to FIG. 13 and FIG. 14, the auxiliary electrode pattern 242 further includes a second auxiliary electrode sub-pattern 2422 disposed between the plurality of light-emitting sub-regions q11, and in the direction d1 perpendicular to the base substrate 21, the thickness h1 of the second auxiliary electrode sub-pattern 2422 is greater than the thickness h2 of the electrode patterning structure 25. With such a structure, a pit w is formed in each light-emitting sub-region q11, thereby improving the light output efficiency of the front side of the electroluminescent layer in each light-emitting sub-region q11. The second auxiliary electrode sub-pattern 2422 and the first auxiliary electrode sub-pattern 2421 are structures formed in the same layer by a single process, and have the same thickness. Certainly, the second auxiliary electrode sub-pattern 2422 and the first auxiliary electrode sub-pattern 2421 may also be structures formed in different layers by two processes, and may have the same thickness or different thicknesses, which is not limited in the embodiments of the present disclosure.

Similarly, in the display panel shown in FIG. 13 and FIG. 14, the light-emitting region q1 includes a plurality of light-emitting sub-regions q11, and each of the light-emitting sub-regions q11 is provided with at least one electroluminescent layer 22. FIG. 13 illustrates a structure in which each light-emitting region q1 includes three light-emitting sub-regions q11, and each of the light-emitting sub-regions q11 is provided with one electroluminescent layer 22. The three light-emitting sub-regions q11 are respectively a red light-emitting sub-region, a green light-emitting sub-region, and a blue light-emitting sub-region, and accordingly, the three light-emitting sub-regions q11 are respectively provided with a blue electroluminescent layer B, a red electroluminescent layer R, and a green electroluminescent layer G.

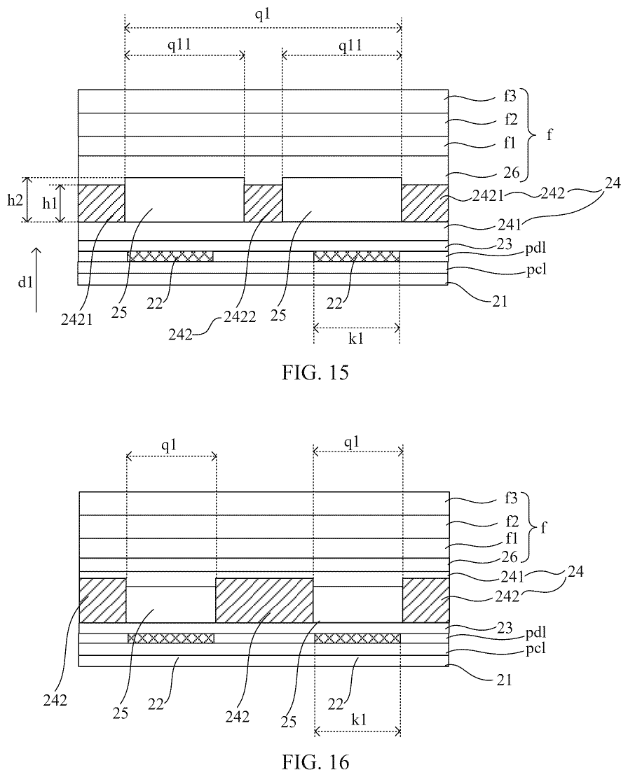

FIG. 15 is a schematic structural diagram of still another display panel according to some embodiments of the present disclosure. In the direction d1 perpendicular to the base substrate 21, the thickness of the auxiliary electrode pattern 242 is less than or equal to the thickness of the electrode patterning structure 25. In this way, when the auxiliary electrode pattern 242 is formed, the auxiliary electrode pattern 242 can be avoided from overflowing toward the upper surface of the electrode patterning structure 25 to affect the aperture rate of the display panel, that is, this structure can increase the aperture rate of the display panel.

In the above embodiments, the auxiliary electrode pattern is disposed on the auxiliary electrode layer, but the auxiliary electrode pattern may also be disposed below the auxiliary electrode layer. Exemplarily, referring to FIG. 16, which is a schematic structural diagram of still another display panel according to some embodiments of the present disclosure, the electrode patterning structure 25 is disposed on the side of the first electrode layer 23 away from the base substrate 21. The auxiliary electrode pattern 242 is disposed in a region where no electrode patterning structure 25 is provided on the auxiliary electrode layer 241. The auxiliary electrode layer 241 is disposed on the side of the auxiliary electrode pattern 242 away from the base substrate 21.

In an exemplary embodiment, the first electrode layer 23, the electrode patterning structure 25, and the auxiliary electrode pattern 242 are formed by an evaporation process. The electrode patterning structure 25 is formed using a fine metal mask (FMM) by an evaporation process. The auxiliary electrode pattern 242 is formed using an open mask by an evaporation process. The auxiliary electrode layer is formed by a sputtering process.

Since the base substrate 21 is oriented differently in the evaporation process and the sputtering process, in the case that the auxiliary electrode pattern 242 is disposed below the auxiliary electrode layer 241, the first electrode layer 23, the electrode patterning structure 25, and the auxiliary electrode pattern 242 are formed first by the evaporation process, and then the base substrate is turned over, and the auxiliary electrode layer 241 is formed by the sputtering process, which can reduce the number of times the base substrate is turned over and improve the manufacturing efficiency of the display panel.

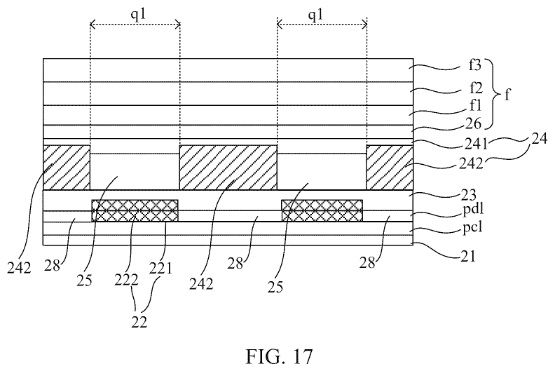

FIG. 17 is a schematic structural diagram of still another display panel according to some embodiments of the present disclosure. The display panel further includes a partition structure 28 disposed between at least two electroluminescent layers 22 of the plurality of electroluminescent layers, and the orthographic projection of the partition structure 28 on the base substrate 21 is within the orthographic projection of the auxiliary electrode pattern 242 on the base substrate 21. With such a structure, when the first electrode layer 23 is fractured under the action of the partition structure 28, the auxiliary electrode pattern 242 can be connected to each portion of the first electrode layer 23 at the fracture, which further increase the reliability of the display panel.

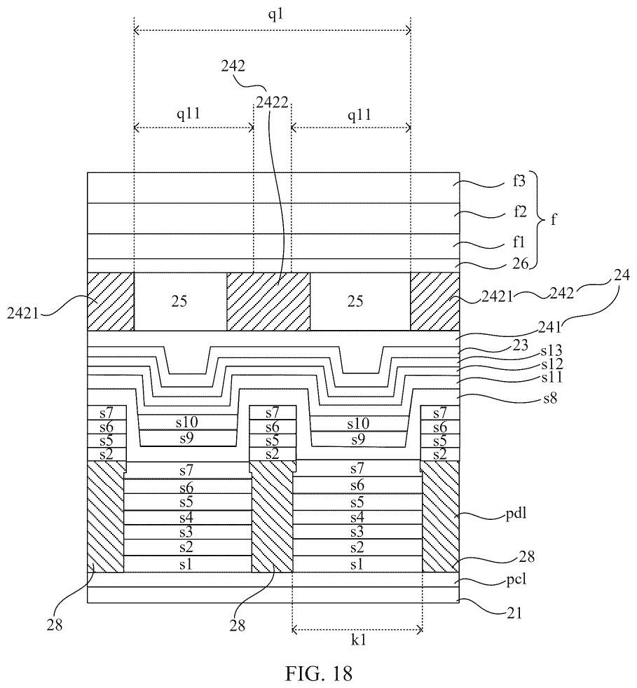

FIG. 17 illustrates a structure in which each light-emitting region q1 is provided with one electroluminescent layer, but each light-emitting region q1 may also be provided with a plurality of electroluminescent structures. Exemplarily, as shown in FIG. 18, which is a schematic structural diagram of still another display panel according to some embodiments of the present disclosure, the light-emitting region q1 includes a plurality of light-emitting sub-regions q11, and each of the light-emitting sub-regions q11 is provided with at least one electroluminescent layer s10.

Additionally, an anode s1, a first hole injection layer (HIL), a first hole transport layer (HTL) s2, a first sub-electroluminescent layer s3, a second sub-electroluminescent layer s4, a first hole block layer (HBL) s5, a first electron transport layer (ETL) s6, a charge generation layer (CGL) s7, a second hole injection layer (HIL), a second hole transport layer (HTL) s8, a third sub-electroluminescent layer s9, a fourth sub-electroluminescent layer s10, a second hole block layer (HBL) s11, a second electron transport layer (ETL) s12, and an electron injection layer (EIL) s13 which are sequentially stacked on the base substrate may also be provided between the first electrode layer 23 and the base substrate 21.

The first sub-electroluminescent layer s3, the second sub-electroluminescent layer s4, the third sub-electroluminescent layer s9, and the fourth sub-electroluminescent layer s10 are the electroluminescent layers in the above embodiments. In different light-emitting sub-regions q11, the first sub-electroluminescent layer s3, the second sub-electroluminescent layer s4, the third sub-electroluminescent layer s9, and the fourth sub-electroluminescent layer s10 may be of different structures. Exemplarily, in the blue light-emitting sub-region for emitting blue light, the first sub-electroluminescent layer s3 is an electron block layer, the second sub-electroluminescent layer s4 is a blue electroluminescent material layer, the third sub-electroluminescent layer s9 is an electron block layer, and the fourth sub-electroluminescent layer s10 is a blue electroluminescent material layer; in the green light-emitting sub-region for emitting green light, the first sub-electroluminescent layer s3 is a green optical cavity length compensation layer, the second sub-electroluminescent layer s4 is a green electroluminescent material layer, the third sub-electroluminescent layer s9 is a green optical cavity length compensation layer, and the fourth sub-electroluminescent layer s10 is a green electroluminescent material layer; and in the red light-emitting sub-region for emitting red light, the first sub-electroluminescent layer s3 is a red optical cavity length compensation layer, the second sub-electroluminescent layer s4 is a red electroluminescent material layer, the third sub-electroluminescent layer s9 is a red optical cavity length compensation layer, and the fourth sub-electroluminescent layer s10 is a red electroluminescent material layer.

In addition, as can be seen from FIG. 18, portions of the first hole injection layer (HIL), the first hole transport layer (HTL) s2, the first hole block layer (HBL) s5, the first electron transport layer (ETL) s6 and the charge generation layer (CGL) s7 are provided on the partition structure 28 in the pixel defining layer pdl, and these portions of the film layers are separated under the action of the partition structure 28 from the first hole transport layer (HTL) s2, the first hole block layer (HBL) s5, the first electron transport layer (ETL) s6 and the charge generation layer (CGL) s7 disposed on the anode s1.

It should be noted that, for the structure between the first electrode layer 23 and the base substrate 21 in some of the display panels provided in the above embodiments, reference may be made to FIG. 18, which is not repeated in the embodiments of the present disclosure.

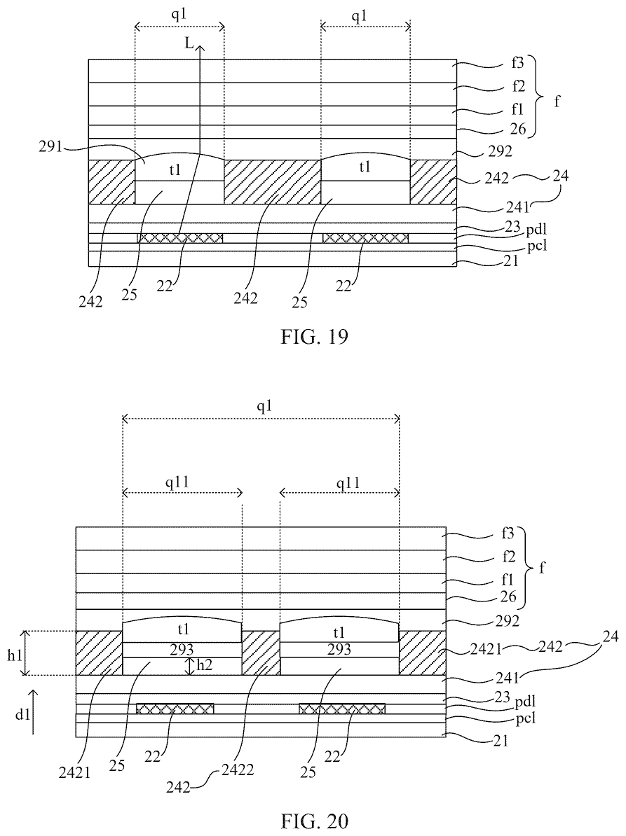

FIG. 19 is a schematic structural diagram of still another display panel according to some embodiments of the present disclosure. The display panel further includes a lens array 291. The lens array 291 is disposed on the side of the light-transmissive electrode patterning structure 25 away from the base substrate 21, and the lens array 291 includes at least one lens structure t1 disposed in the light-emitting region q1.

The display panel further includes a second planarization layer 292, and the second planarization layer 292 is disposed between the lens array 291 and the first light extraction layer 26. The refractive index of the material of the second planarization layer 292 is less than the refractive index of the material of the lens structure t1. By providing the lens structure t1 and the second planarization layer 292, the light output efficiency of the front side of the display panel can be improved. Exemplarily, the lens structure t1 is a convex lens, which can converge the light L towards the center, thereby improving the light output efficiency of the front side of the display panel.

An encapsulation layer f is further provided on the second planarization layer 292, that is, the lens array 291 is disposed in an encapsulation structure formed of the encapsulation layer f and the base substrate 21. For the structure of the encapsulation layer f, reference may be made to the above embodiments, which is not repeated herein. In addition, the second planarization layer 292 may also belong to the encapsulation layer f, which is not limited in the embodiments of the present disclosure.

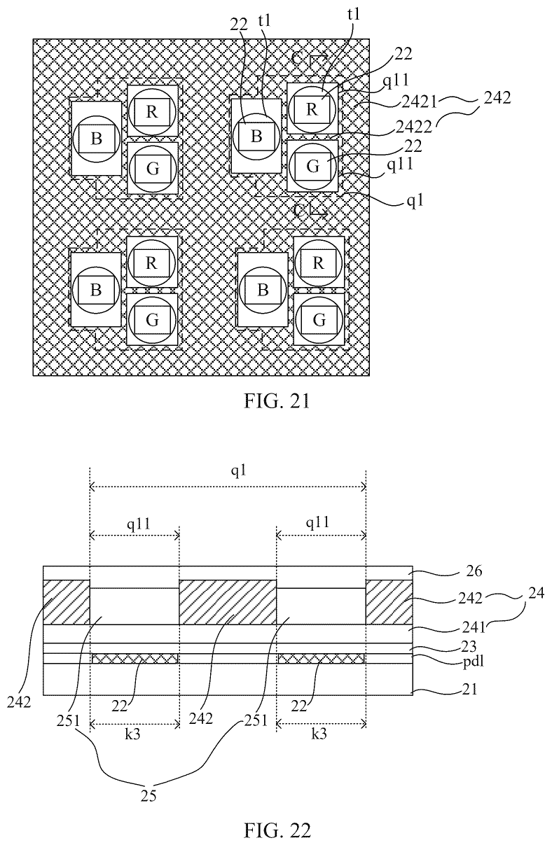

FIG. 20 is a schematic structural diagram of still another display panel according to some embodiments of the present disclosure, and FIG. 21 is a schematic diagram of a top view structure of the display panel shown in FIG. 20 (FIG. 20 is a schematic diagram of a sectional structure at position C-C of FIG. 21). Referring to FIG. 20 and FIG. 21, the light-emitting region q1 includes a plurality of light-emitting sub-regions q11, and each of the light-emitting sub-regions q11 is provided with at least one electroluminescent layer 22.

The lens array 291 includes a plurality of lens structures t1 respectively disposed in the plurality of light-emitting sub-regions q11, and the lens structure t1 adjusts the light emitted from the electroluminescent layer 22 in each light-emitting sub-region, thereby improving the light output efficiency of the front side of the electroluminescent layer 22 in each light-emitting sub-region.

In this solution, the auxiliary electrode layer 241 is disposed on the side of the first electrode layer 23 away from the base substrate 21 (the auxiliary electrode layer 241 is in contact with the first electrode layer 23), the electrode patterning structure 25 is disposed on the side of the auxiliary electrode layer 241 away from the base substrate 21, the auxiliary electrode pattern 242 is disposed in a region where no electrode patterning structure 25 is provided on the auxiliary electrode layer 241, and the lens structure t1 is disposed on the side of the electrode patterning structure 25 away from the base substrate 21.

In an exemplary embodiment, the display panel further includes a spacer layer 293. The spacer layer 293 is disposed on the side of the electrode patterning structure 25 away from the base substrate 21, and the lens structure t1 is disposed on the side of the spacer layer 293 away from the base substrate 21. The material of the spacer layer 293 includes a hydrophobic material. Since the electrode patterning structure 25 has certain material selectivity, the spacer layer 293 is formed on the electrode patterning structure 25, and the lens structure t1 is formed on the spacer layer 293, which can reduce the difficulty of forming the lens structure t1.

In some embodiments, the light-emitting region q1 includes a plurality of light-emitting sub-regions q11, and each of the light-emitting sub-regions q11 is provided with at least one electroluminescent layer 22.

In an exemplary embodiment, the auxiliary electrode pattern 242 includes a first auxiliary electrode sub-pattern 2421 surrounding the light-emitting region q1 and a second auxiliary electrode sub-pattern 2422 disposed between the plurality of light-emitting sub-regions q11. In the direction d1 perpendicular to the base substrate 21, the thickness h1 of the auxiliary electrode pattern 242 is greater than the thickness h2 of the electrode patterning structure 25. In this structure, a pit is formed in each of the light-emitting sub-regions q11 of the light-emitting region, and the lens structure t1 is disposed in the pit. Certainly, the thickness h1 of the auxiliary electrode pattern 242 may also be equal to the thickness h2 of the electrode patterning structure 25, and the lens structure t1 covers the auxiliary electrode pattern 242 and the electrode patterning structure 25.

It should be noted that the above embodiments provide various structures in the light-emitting region and the light emitting sub-regions, and the display panel provided in the embodiments of the present disclosure may also have a plurality of light-emitting regions, and the structures in the plurality of light-emitting regions may be at least one of the structures provided in the above embodiments.

In the embodiments of the present disclosure, since the light output efficiency of the front side of the display panel provided is improved, the display panel has a good display effect while the power consumption is reduced. Furthermore, the auxiliary electrode structure in the display panel reduces the possibility of damage to the display panel when it is bent and folded, and thus the flexibility of the display panel is improved. Therefore, the display panel provided in the embodiments of the present disclosure is applicable to a variety of display devices such as laptop computers, in-vehicle displays, smartphones, and smart wearable devices.

In summary, the embodiments of the present disclosure provide a display panel. In the display panel, an auxiliary electrode structure including an auxiliary electrode layer and an auxiliary electrode pattern is provided on the first electrode layer, and the auxiliary electrode layer or the auxiliary electrode pattern is in contact with the first electrode layer. With this structure, on the one hand, the first electrode layer can be protected, and the probability of fracture of the first electrode layer can be reduced; and on the other hand, in the event that the first electrode layer fractures, the first electrode layer can be electrically connected to the auxiliary electrode structure at the position of fracture, which can prevent the electrical function of the first electrode layer from damage, thereby solving the problem of the lower yield of the display panel in the related art and improving the yield of the display panel.

Additionally, the first light extraction layer is provided on the auxiliary electrode structure and the light-transmissive electrode patterning structure, and the refractive index of the first light extraction layer is less than the refractive index of the auxiliary electrode structure and the refractive index of the light-transmissive electrode patterning structure, such that the first light extraction layer, the auxiliary electrode structure, and the light-transmissive electrode patterning structure can cooperate to achieve the light extraction function, which improves the light output efficiency of the front side of the display panel. The auxiliary electrode structure and the light-transmissive electrode patterning structure are reused as a part of a light extraction structure, which reduces the influence of the auxiliary electrode structure and the light-transmissive electrode patterning structure on the display panel.

FIG. 22 is a sectional schematic diagram of the display panel shown in FIG. 4 (FIG. 22 is another sectional schematic diagram at position D-D of FIG. 4). Referring to FIG. 22 and FIG. 4, the embodiments of the present disclosure further provide a display panel, including:
a base substrate 21, and the base substrate 21 has a display region aa and a peripheral region pa around the display region aa; the display region aa includes a plurality of light-emitting regions q1, and each of the light-emitting regions q1 includes a plurality of light-emitting sub-regions q11;
a plurality of electroluminescent layers 22 disposed on base substrate 21;
a first electrode layer 23, disposed on the side of the plurality of electroluminescent layers 22 away from the base substrate 21;
an auxiliary electrode structure 24 and a light-transmissive electrode patterning structure 25. The auxiliary electrode structure 24 and the electrode patterning structure 25 are disposed on the side of the first electrode layer 23 away from the base substrate 21. The auxiliary electrode structure 24 includes an auxiliary electrode layer 241 and an auxiliary electrode pattern 242 stacked on each other, and one of the auxiliary electrode layer 241 and the auxiliary electrode pattern 242 is in contact with the first electrode layer 23. The auxiliary electrode pattern 242 is provided with a plurality of auxiliary electrode openings k3, and the orthographic projection of at least one auxiliary electrode opening k3 of the plurality of auxiliary electrode openings k3 on the base substrate 21 is at least partially within the light-emitting sub-region q11. The electrode patterning structure 25 includes a plurality of electrode patterning sub-structures 251, and the electrode patterning sub-structure 251 is disposed in the auxiliary electrode opening k3.

In summary, the embodiments of the present disclosure provide a display panel. In the display panel, an auxiliary electrode structure including an auxiliary electrode layer and an auxiliary electrode pattern is provided on the first electrode layer, and the auxiliary electrode layer or the auxiliary electrode pattern is in contact with the first electrode layer. With this structure, on the one hand, the first electrode layer can be protected, and the probability of fracture of the first electrode layer can be reduced; and on the other hand, in the event that the first electrode layer fractures, the first electrode layer can be electrically connected to the auxiliary electrode structure at the position of fracture, which can prevent the electrical function of the first electrode layer from damage, thereby solving the problem of the lower yield of the display panel in the related art and improving the yield of the display panel.

According to some embodiments of the present disclosure, a display device is provided. The display device includes any one of the display panels provided in the above embodiments.

Since the light output efficiency of the front side is improved, a good display effect is achieved while the power consumption is reduced. Furthermore, the auxiliary electrode structure in the display panel reduces the possibility of damage to the display panel when it is bent and folded, and thus the flexibility of the display panel is improved. Therefore, the display panel provided in the embodiments of the present disclosure is applicable to a variety of display devices such as laptop computers, in-vehicle displays, smartphones, and smart wearable devices.

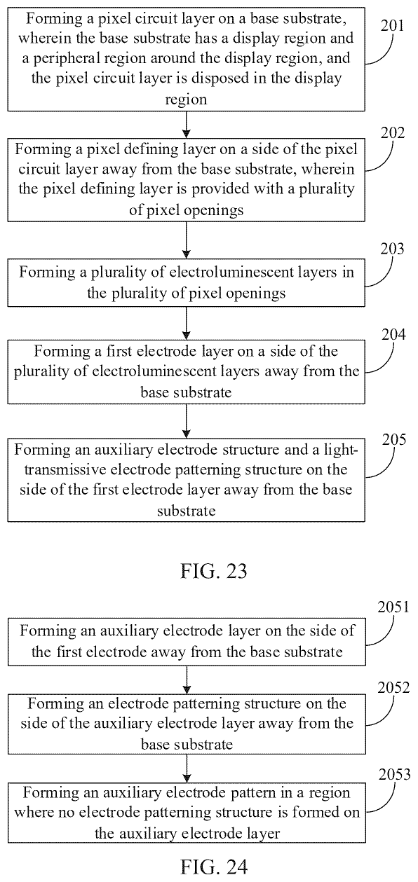

FIG. 23 is a flowchart of a method for manufacturing a display panel according to some embodiments of the present disclosure.

In step 201, a pixel circuit layer is formed on a base substrate. The base substrate has a display region and a peripheral region around the display region, and the pixel circuit layer is disposed in the display region.

In step 202, a pixel defining layer is formed on a side of the pixel circuit layer away from the base substrate, and the pixel defining layer is provided with a plurality of pixel openings.

In step 203, a plurality of electroluminescent layers are formed in the plurality of pixel openings.

In step 204, a first electrode layer is formed on a side of the plurality of electroluminescent layers away from the base substrate.

In step 205, an auxiliary electrode structure and a light-transmissive electrode patterning structure are formed on the side of the first electrode layer away from the base substrate.

The auxiliary electrode structure includes an auxiliary electrode layer and an auxiliary electrode pattern, and one of the auxiliary electrode layer and the auxiliary electrode pattern is in contact with the first electrode layer. The orthographic projection of the electrode patterning structure on the base substrate is overlapped with the orthographic projection of at least one pixel opening of the plurality of pixel openings on the base substrate, and the orthographic projection of the auxiliary electrode pattern on the base substrate is not overlapped with the orthographic projection of the electrode patterning structure on the base substrate.

In summary, the embodiments of the present disclosure provide a display panel. In the display panel, an auxiliary electrode structure including an auxiliary electrode layer and an auxiliary electrode pattern is provided on the first electrode layer, and the auxiliary electrode layer or the auxiliary electrode pattern is in contact with the first electrode layer. With this structure, on the one hand, the first electrode layer can be protected, and the probability of fracture of the first electrode layer can be reduced; and on the other hand, in the event that the first electrode layer fractures, the first electrode layer can be electrically connected to the auxiliary electrode structure at the position of fracture, which can prevent the electrical function of the first electrode layer from damage, thereby solving the problem of the lower yield of the display panel in the related art and improving the yield of the display panel.

In some embodiments, the method further includes forming a first light extraction layer on the base substrate on which the auxiliary electrode structure and the light-transmissive electrode patterning structure are formed. The refractive index of the first light extraction layer is less than the refractive index of the auxiliary electrode structure and the refractive index of the light-transmissive electrode patterning structure.

As shown in FIG. 24, and FIG. 24 is a flowchart of forming an auxiliary electrode structure and a light-transmissive electrode patterning structure in the embodiment shown in FIG. 23.

Step 205 includes the following sub-steps.

In sub-step 2051, an auxiliary electrode layer is formed on the side of the first electrode away from the base substrate.

The auxiliary electrode layer is formed by a sputtering process. In addition, the material of the auxiliary electrode layer 241 includes a transparent conductive oxide. Since the auxiliary electrode layer 241 is an entire layer structure, the auxiliary electrode layer 241 is made of a transparent conductive oxide with a high light transmittance, e.g., indium zinc oxide (IZO) and so forth, and the transparent conductive oxide has a certain resistance to water and oxygen. Thus, the auxiliary electrode layer can increase the durability of the display panel. In order to reduce the possibility of fracture of the first electrode layer, the auxiliary electrode layer is thicker. For example, the thickness of the auxiliary electrode layer ranges from 50 nm to 1000 nm. The first electrode layer is a cathode layer, and the auxiliary electrode layer is an auxiliary cathode layer.

In sub-step 2052, an electrode patterning structure is formed on the side of the auxiliary electrode layer away from the base substrate.

The electrode patterning structure is a structure which is used in cooperation to form the auxiliary electrode pattern, and the electrode patterning structure is made of a material that selectively precipitates the material of the auxiliary electrode pattern, that is, it is difficult for the material of the auxiliary electrode pattern to be deposited on the electrode patterning structure, and when the auxiliary electrode pattern is formed after the electrode patterning structure is provided, the auxiliary electrode pattern is formed only in a region where no electrode patterning structure is provided.

The thickness of the electrode patterning structure ranges from 5 nm to 100 nm or from 15 nm to 100 nm, which can improve the electrode patterning structure's property of preventing magnesium and argentum from forming films on the surface of the electrode patterning structure. For the structure of the electrode patterning structure, reference may be made to FIG. 5 above.

In sub-step 2053, an auxiliary electrode pattern is formed in a region where no electrode patterning structure is formed on the auxiliary electrode layer.

Since the electrode patterning structure is formed, the auxiliary electrode pattern is formed only in the region where no electrode patterning structure is provided. The orthographic projection of the auxiliary electrode pattern on the base substrate is at least partially overlapped with the orthographic projection of the pixel defining layer on the base substrate. For the structure of the auxiliary electrode pattern, reference may be made to FIG. 5 above.

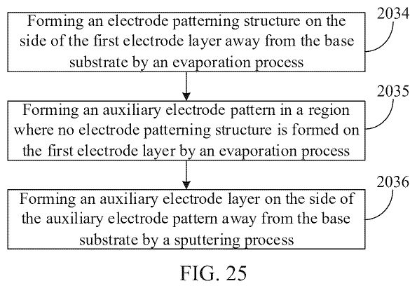

FIG. 25 is another flowchart of forming an auxiliary electrode structure and a light-transmissive electrode patterning structure in the embodiment shown in FIG. 23.

Step 203 includes the following sub-steps.

In sub-step 2034, an electrode patterning structure is formed on the side of the first electrode layer away from the base substrate by an evaporation process.

In some embodiments, prior to this step, step 202 includes forming the first electrode layer on the side of the plurality of electroluminescent layers away from the base substrate by an evaporation process, that is, the first electrode layer and the electrode patterning structure are both formed by the evaporation process. Specifically, the electrode patterning structure is formed using a fine metal mask (FMM) by an evaporation process, and for the structure of the electrode patterning structure, reference may be made to FIG. 16 in the above embodiment.

In this method, the first electrode layer and the electrode patterning structure are formed by the evaporation process, without the need to turn over the base substrate, which simplifies the manufacturing process of the display panel and improving the manufacturing efficiency of the display panel.

In sub-step 2035, an auxiliary electrode pattern is formed in a region where no electrode patterning structure is formed on the first electrode layer by an evaporation process.

The auxiliary electrode pattern may also be formed by the evaporation process. In some embodiments, the auxiliary electrode pattern is formed using an open mask by the evaporation process, and for the structure of the auxiliary electrode pattern, reference may be made to FIG. 16 in the above embodiment.

In sub-step 2036, an auxiliary electrode layer is formed on the side of the auxiliary electrode pattern away from the base substrate by a sputtering process.

The auxiliary electrode layer is formed by the sputtering process. The base substrate is oriented differently in the sputtering process and the evaporation process. The base substrate is turned over in sub-step 2036, and the auxiliary electrode layer is formed by the sputtering process on the base substrate on which the auxiliary electrode pattern is formed.

For the various structures of the display panels involved in the methods provided in the embodiments of the present disclosure, reference may be made to the various embodiments described above, which are not repeated herein.

The expression “at least one of A and B” in the present disclosure merely describes an association relationship of associated objects, indicating three kinds of relationships. For example, at least one of A and B may be expressed as: A exits alone, A and B exit simultaneously, and B exits alone. Similarly, “at least one of A, B and C” indicates seven kinds of relationships, and may be expressed: A exits alone, B exits alone, C exits alone, A and B exit simultaneously, A and C exit simultaneously, C and B exit simultaneously, and A, B, and C exit simultaneously. Similarly, “at least one of A, B, C and D” indicates fifteen kinds of relationships, and may be expressed as: A exits alone, B exits alone, C exits alone, D exits alone, A and B exit simultaneously, A and C exit simultaneously, A and D exit simultaneously, C and B exit simultaneously, D and B exit simultaneously, C and D exit simultaneously, A, B and C exit simultaneously, A, B and D exit simultaneously, A, C and D exit simultaneously, B, C and D exit simultaneously, and A, B, C and D exit simultaneously.

It should be noted that in the accompanying drawings, the dimensions of the layers and regions may be exaggerated for the clarity of illustration. It is understandable that when an element or layer is referred to as being “on” another element or layer, it may be directly on the other element, or an intermediate layer may exist. Also, it is understandable that when an element or layer is referred to as being “below” another element or layer, it may be directly below the other element, or more than one intermediate layer or element may exist. It is also understandable that when a layer or element is referred to as being “between” two layers or elements, it may be the only layer between the two layers or elements, or more than one intermediate layer or element may exist. Similar reference marks indicate similar elements throughout.

In the present disclosure, the terms “first”, “second”, “third” and “fourth” are merely used for descriptive purposes and are not to be construed as indicate or imply any relative importance. The term “a plurality of” refers to two or more, unless otherwise expressly specified.

Described above are merely optional embodiments of the present disclosure, and are not intended to limit the present disclosure. Within the principles of the present disclosure, any modifications, equivalent substitutions, improvements, and the like are within the protection scope of the present disclosure.

1. A display panel, comprising:
a base substrate, having a display region and a peripheral region around the display region;
a pixel circuit layer, disposed on a side of the base substrate and in the display region;
a pixel defining layer, disposed on a side of the pixel circuit layer away from the base substrate, wherein the pixel defining layer is provided with a plurality of pixel openings;
a plurality of electroluminescent layers, disposed in the plurality of pixel openings;
a first electrode layer, disposed on a side of the plurality of electroluminescent layers away from the base substrate; and
an auxiliary electrode structure and a light-transmissive electrode patterning structure, wherein the auxiliary electrode structure and the electrode patterning structure are disposed on a side of the first electrode layer away from the base substrate, the auxiliary electrode structure comprises an auxiliary electrode layer and an auxiliary electrode pattern, one of the auxiliary electrode layer and the auxiliary electrode pattern is in contact with the first electrode layer, an orthographic projection of the electrode patterning structure on the base substrate is overlapped with an orthographic projection of at least one pixel opening of the plurality of pixel openings on the base substrate, and an orthographic projection of the auxiliary electrode pattern on the base substrate is not overlapped with the orthographic projection of the electrode patterning structure on the base substrate.

2. The display panel according to claim 1, further comprising:
a first light extraction layer disposed on sides of the auxiliary electrode structure and the light-transmissive electrode patterning structure that are away from the base substrate, wherein a refractive index of the first light extraction layer is less than a refractive index of the auxiliary electrode structure and a refractive index of the light-transmissive electrode patterning structure.

3. The display panel according to claim 2, wherein
the auxiliary electrode layer is disposed on the side of the first electrode layer away from the base substrate;
the electrode patterning structure is disposed on a side of the auxiliary electrode layer away from the base substrate;
the auxiliary electrode pattern is disposed in a region where no electrode patterning structure is provided on the auxiliary electrode layer, and the orthographic projection of the auxiliary electrode pattern on the base substrate is at least partially overlapped with an orthographic projection of the pixel defining layer on the base substrate.

4. The display panel according to claim 3, wherein
the auxiliary electrode pattern comprises a first auxiliary electrode sub-pattern at least partially surrounding the pixel opening, wherein in a direction perpendicular to the base substrate, a thickness of the first auxiliary electrode sub-pattern is greater than a thickness of the electrode patterning structure;
the display panel further comprises a first planarization layer, wherein the first planarization layer is disposed on a side of the first light extraction layer away from the base substrate, and a refractive index of the first planarization layer is greater than the refractive index of the first light extraction layer.

5. The display panel according to claim 4, wherein the display region comprises a plurality of light-emitting regions, each of the plurality of light-emitting regions comprises a plurality of light-emitting sub-regions, and each of the plurality of light-emitting sub-regions is provided with at least one electroluminescent layer;
the auxiliary electrode pattern further comprises a second auxiliary electrode sub-pattern disposed between the plurality of light-emitting sub-regions, wherein in the direction perpendicular to the base substrate, a thickness of the second auxiliary electrode sub-pattern is greater than the thickness of the electrode patterning structure.

6. The display panel according to claim 5, wherein in the direction perpendicular to the base substrate, a sum of the thickness of the electrode patterning structure and a thickness of the first light extraction layer is less than a thickness of the auxiliary electrode pattern.

7. The display panel according to claim 3, wherein in a direction perpendicular to the base substrate, a thickness of the auxiliary electrode pattern is less than or equal to a thickness of the electrode patterning structure.

8. The display panel according to claim 2, wherein
the electrode patterning structure is disposed on the side of the first electrode layer away from the base substrate;
the auxiliary electrode pattern is disposed in a region where no electrode patterning structure is provided on the auxiliary electrode layer;
the auxiliary electrode layer is disposed on a side of the auxiliary electrode pattern away from the base substrate.

9. The display panel according to claim 8, wherein the pixel defining layer comprises a partition structure disposed between at least two electroluminescent layers of the plurality of electroluminescent layers; wherein
an orthographic projection of the partition structure on the base substrate is within the orthographic projection of the auxiliary electrode pattern on the base substrate.

10. The display panel according to claim 8, wherein the first electrode layer, the electrode patterning structure and the auxiliary electrode pattern are formed by an evaporation process.

11. The display panel according to claim 2, further comprising: a lens array, wherein the lens array is disposed on a side of the electrode patterning structure away from the base substrate, and the lens array comprises at least one lens structure disposed in the display region;
the display panel further comprises a second planarization layer, wherein the second planarization layer is disposed between the lens array and the first light extraction layer, and a refractive index of a material of the second planarization layer is less than a refractive index of a material of the lens structure.

12. The display panel according to claim 11, wherein the display region comprises a plurality of light-emitting regions, each of the plurality of light-emitting regions comprises a plurality of light-emitting sub-regions, and each of the plurality of light-emitting sub-regions is provided with at least one electroluminescent layer;
the lens array comprises a plurality of lens structures respectively disposed in the plurality of light-emitting sub-regions.

13. The display panel according to claim 11, wherein the auxiliary electrode layer is disposed on the side of the first electrode layer away from the base substrate, the electrode patterning structure is disposed on a side of the auxiliary electrode layer away from the base substrate, and the auxiliary electrode pattern is disposed in a region where no electrode patterning structure is provided on the auxiliary electrode layer;
the lens structure is disposed on the side of the electrode patterning structure away from the base substrate.

14. The display panel according to claim 13, wherein the display region comprises a plurality of light-emitting regions, each of the plurality of light-emitting regions comprises a plurality of light-emitting sub-regions, and each of the plurality of light-emitting sub-regions is provided with at least one electroluminescent layer;
the auxiliary electrode pattern comprises a first auxiliary electrode sub-pattern surrounding the light-emitting region and a second auxiliary electrode sub-pattern disposed between the plurality of light-emitting sub-regions, wherein in a direction perpendicular to the base substrate, a thickness of the auxiliary electrode pattern is greater than a thickness of the electrode patterning structure.

15. The display panel according to claim 14, further comprising: a spacer layer, wherein the spacer layer is disposed on the side of the electrode patterning structure away from the base substrate, and the lens structure is disposed on a side of the spacer layer away from the base substrate.

16. The display panel according to claim 2, further comprising: an encapsulation layer; wherein
the encapsulation layer comprises the first light extraction layer and a first light-transmissive layer, a second light-transmissive layer, and a third light transmittance layer sequentially stacked on the first light extraction layer, wherein a refractive index of the first light-transmissive layer is greater than a refractive index of the second light-transmissive layer and the refractive index of the first light extraction layer, and the refractive index of the second light-transmissive layer is less than a refractive index of the third light-transmissive layer.

17. The display panel according to claim 16, wherein a material of the first light extraction layer comprises silicon oxide, a material of the first light-transmissive layer comprises silicon nitride oxide or silicon nitride, a material of the second light-transmissive layer comprises a resin material, and a material of the third light-transmissive layer comprises silicon nitride;
a material of the auxiliary electrode layer comprises a transparent conductive oxide, and a material of the auxiliary electrode pattern comprises a conductive metal material.

18. The display panel according to claim 17, wherein
a thickness of the first light extraction layer ranges from 10 nm to 1000 nm, thicknesses of the first light-transmissive layer and the third light-transmissive layer range from 600 nm to 1200 nm, and a thickness of the second light-transmissive layer ranges from 3 μm to 5 μm;
a thickness of the auxiliary electrode layer ranges from 50 nm to 1000 nm, and a thickness of the electrode patterning structure ranges from 5 nm to 100 nm.

19. A display panel, comprising:
abase substrate, having a display region and a peripheral region around the display region, wherein the display region comprises a plurality of light-emitting regions, and each of the plurality of light-emitting regions comprises a plurality of light-emitting sub-regions;
a plurality of electroluminescent layers, disposed on the base substrate;
a first electrode layer, disposed on a side of the plurality of electroluminescent layers away from the base substrate; and
an auxiliary electrode structure and a light-transmissive electrode patterning structure, wherein the auxiliary electrode structure and the electrode patterning structure are disposed on a side of the first electrode layer away from the base substrate, the auxiliary electrode structure comprises an auxiliary electrode layer and an auxiliary electrode pattern which are stacked on each other, one of the auxiliary electrode layer and the auxiliary electrode pattern is in contact with the first electrode layer, the auxiliary electrode pattern is provided with a plurality of auxiliary electrode openings, an orthographic projection of at least one auxiliary electrode opening of the plurality of auxiliary electrode openings on the base substrate is at least partially within the light-emitting sub-region, and the electrode patterning structure comprises a plurality of electrode patterning sub-structures, the electrode patterning sub-structures being disposed in the auxiliary electrode openings.

20. A display device, comprising a display panel, wherein the display panel comprises:
abase substrate, having a display region and a peripheral region around the display region; a pixel circuit layer, disposed on a side of the base substrate and in the display region;
a pixel defining layer, disposed on a side of the pixel circuit layer away from the base substrate, wherein the pixel defining layer is provided with a plurality of pixel openings;
a plurality of electroluminescent layers, disposed in the plurality of pixel openings;
a first electrode layer, disposed on a side of the plurality of electroluminescent layers away from the base substrate; and
an auxiliary electrode structure and a light-transmissive electrode patterning structure, wherein the auxiliary electrode structure and the electrode patterning structure are disposed on a side of the first electrode layer away from the base substrate, the auxiliary electrode structure comprises an auxiliary electrode layer and an auxiliary electrode pattern, one of the auxiliary electrode layer and the auxiliary electrode pattern is in contact with the first electrode layer, an orthographic projection of the electrode patterning structure on the base substrate is overlapped with an orthographic projection of at least one pixel opening of the plurality of pixel openings on the base substrate, and an orthographic projection of the auxiliary electrode pattern on the base substrate is not overlapped with the orthographic projection of the electrode patterning structure on the base substrate.
